(19) United States
(12) Patent Application Publication
(10) Pub. No.: US 2025/0300020 A1
(43) Pub. Date: Sep. 25, 2025

(54) Dicing method of semiconductor structure and semiconductor structure

(71) Applicant: UNITED MICROELECTRONICS CORP., Hsin-Chu City (TW)

(72) Inventors: Kai-Kuang Ho, Hsinchu City (TW); Yi-Feng Hsu, Hsinchu City (TW); Yu-Jie Lin, Taichung City (TW)

(73) Assignee: UNITED MICROELECTRONICS CORP., Hsin-chu City (TW)

(21) Appl. No.: 18/646,734

(22) Filed: Apr. 25, 2024

(30) Foreign Application Priority Data
Mar. 22, 2024 (TW) 113110724

(51) Int. Cl. H01L 21/78; H01L 23/00

(52) U.S. Cl. CPC H01L 21/78; H01L 24/05; H01L 24/08; H01L 24/80; H01L 24/94; H01L 24/97; H01L 2224/05624; H01L 2224/05639; H01L 2224/05644; H01L 2224/05647; H01L 2224/05657; H01L 2224/05684; H01L 2224/08145; H01L 2224/80357; H01L 2224/80379; H01L 2224/80896; H01L 2224/94; H01L 2224/97; H01L 2924/05042; H01L 2924/0544; H01L 2924/059

(57) ABSTRACT

The invention provides a method for dicing a semiconductor structure, which comprises the following steps: providing a wafer with a front surface and a back surface, forming at least one dielectric layer on the front surface of the wafer and at least one first hybrid contact structure in the dielectric layer, wherein the surface of the first hybrid contact structure is exposed, performing a dry etching step to form a plurality of grooves on the front surface of the wafer, and performing a blade saw step to form a plurality of dicing grooves from the back surface of the wafer, and dicing the wafer into a plurality of dies.

### BACKGROUND OF THE INVENTION

### 1. Field of the Invention

The present invention relates to the field of semiconductor manufacturing, in particular to a method for dicing a wafer containing a hybrid bond contact.

### 2. Description of the Prior Art

In the current technology, hybrid bonding technology is a common means. For example, contact structures formed on two different substrates can contact each other and be electrically connected by hybrid bonding. Compared with connection methods such as wiring or forming solder bumps, this bonding method can greatly reduce the area and improve the device density, so hybrid bonding technology is more and more widely used in the field of semiconductor manufacturing.

However, in the hybrid bonding technology, the quality of components is required, because the hybrid bonding technology directly touches and electrically connects two hybrid contact structures, so if the surfaces of the two hybrid contact structures are uneven, the contact quality will be affected, and even the circuit may be opened.

Therefore, a method is needed to improve the surface flatness of components in the process of hybrid contact structure.

### SUMMARY OF THE INVENTION

The invention provides a method for dicing a semiconductor structure, which comprises the following steps: providing a wafer with a front surface and a back surface, forming at least one dielectric layer on the front surface of the wafer and at least one first hybrid contact structure in the dielectric layer, wherein the surface of the first hybrid contact structure is exposed, performing a dry etching step to form a plurality of grooves on the front surface of the wafer, and performing a blade saw step to form a plurality of dicing grooves from the back surface of the wafer, and dicing the wafer into a plurality of dies.

The invention provides a semiconductor structure, which comprises a chip, wherein the chip comprises a substrate, and the substrate comprises a front surface and a back surface, wherein the wafer comprises an element region and a non-circuit region, and the non-circuit region is on one side of the element region, wherein the substrate comprises a sharp corner portion, the sharp corner portion is located in the non-circuit region, at least one dielectric layer is located on the front surface of the substrate in the element region and the non-circuit region, and at least one first hybrid contact structure is located in the dielectric layer and the element region, wherein the surface of the first hybrid contact structure is exposed.

The present invention is characterized by providing a method for dicing a wafer, especially a method for dicing a wafer containing a hybrid bond contact. Because the wafer contains hybrid contact structures, it requires high surface flatness. If the wafer is cut by conventional methods such as laser dicing or stealth dicing, it may cause problems such as slag or difficult to control the cross section. The method comprises the following steps: firstly, forming a groove on the front side of a wafer by dry etching, and then dicing the wafer from the back side of the wafer by a blade saw step. The groove on the front side of the wafer is formed by dry etching, so that no slag is generated, the flatness of the hybrid contact structure on the front side of the wafer can be maintained, and the quality of the cut dies can be improved. In addition, the back surface of the wafer is diced by the blade saw, so that the dicing speed of the wafer can be maintained and the dicing efficiency can be prevented from being excessively slowed down by the etching step.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic cross-sectional structure of a wafer of the present invention before dicing.

FIG. 2, FIG. 3 and FIG. 4 are schematic cross-sectional views of a wafer dicing step according to an embodiment of the present invention.

FIG. 5 shows a schematic cross-sectional structure of a cut die.

FIG. 6 is a schematic cross-sectional view showing that a plurality of cut dies bonded to another wafer.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

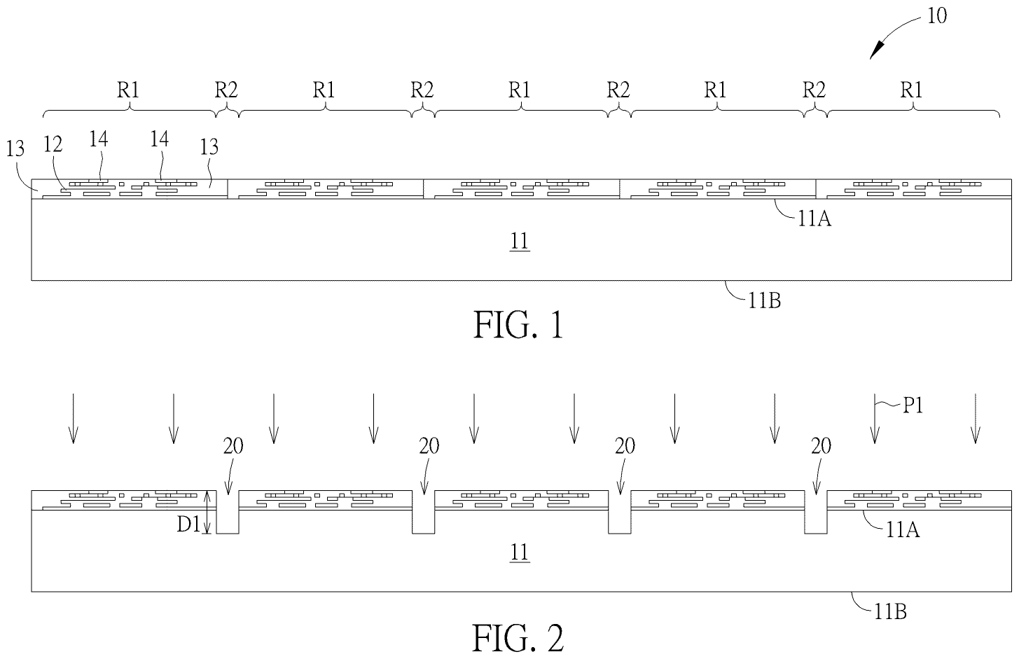

Please refer to FIG. 1, which shows a schematic cross-sectional structure of a wafer of the present invention before dicing. First, a wafer 10 is provided. The wafer 10 includes a substrate 11, such as a silicon substrate. The substrate 11 is defined with a front surface 11A and a back surface 11B, and a circuit layer 12 is formed on the front surface 11A of the substrate 11, wherein the circuit layer 12 may include electronic components or conductive structures, such as transistors, capacitors, inductors, resistors, power amplifiers, contact structures, conductor patterns, etc. The above-mentioned electronic components or conductive structures are formed in a dielectric layer 13 and may be stacked on each other in a multilayer manner. Among them, at least one hybrid contact structure 14 is formed at the top of the multilayer circuit layer, and the hybrid contact structure 14 is electrically connected with the lower circuit layer 12, and in the following steps, the hybrid contact structure 14 will be used to touch and electrically connect with another hybrid contact structure (not shown). The above technology is also called hybrid bonding technology. As mentioned in the prior art, using hybrid contact to make different components contact and electrically connect with each other can greatly reduce the area and improve the component density compared with connection methods such as wiring or forming solder bumps.

In addition, the wafer 10 includes a plurality of element regions R1 and a plurality of non-circuit region R2, each non-circuit region R2 is disposed between two element regions R1, wherein the element region R1 contains the above-mentioned circuit layer 12, such as various electronic elements or conductive metal layers, while the non-circuit region R2 does not contain the circuit layer 12, that is, it does not contain electronic elements or conductive metal layers, but only contains the dielectric layer 13. The subsequent dicing step can be cut in the non-circuit region R2, so that the electronic components in the circuit layer 12 will not be affected.

In FIG. 1, the circuit layer 12 includes, for example, a transistor and a conductive layer in a dielectric layer, wherein the material of the transistor may include polysilicon or metal, and the material of the conductive layer and the hybrid contact structure 14 may include metals with good conductivity such as tungsten, cobalt, copper, aluminum, gold, silver, etc. The dielectric layer can contain insulating materials such as silicon nitride, silicon oxide and silicon oxynitride. However, the above materials are only some examples of the present invention, and the present invention is not limited thereto.

After the circuit layer 12 and the hybrid contact structure 14 on the substrate 11 are completed, the wafer 10 needs to be cut to form a plurality of dies. In the conventional step, the wafer 10 may be cut into a plurality of dies by laser dicing, blade saw dicing or Stealth Dicing. However, the above-mentioned dicing methods all have their shortcomings, such as laser dicing and blade saw dicing, which will produce a lot of residues, such as slag or various residual particles, which will affect the surface of the cut die. Especially, when the top layer of the die contains the hybrid contact structure 14, the flatness of the component surface is required to be higher. If the flatness of the component surface becomes worse due to the residue, it is likely that the hybrid contact structure 14 on the surface will not be electrically connected with another hybrid contact structure, and then the problem of disconnection will occur. As for stealth dicing, it is a method of dividing the wafer into dies by focusing the laser inside the silicon wafer and forming a metamorphic layer inside it, and divides the wafer into dies by expanding film. The above stealth dicing step forms the metamorphic layer inside the silicon wafer and produces a fracture starting point. However, due to the complex structure, it is not easy to get a good crack surface when using the expandable film to separate the dies, which is easy to cause the problem of device falling off or damage.

Therefore, several commonly used wafer dicing methods are no longer suitable for wafers with hybrid contact structures on the top surface, so it is necessary to find other wafer dicing methods to avoid affecting the quality of hybrid contact structures during dicing.

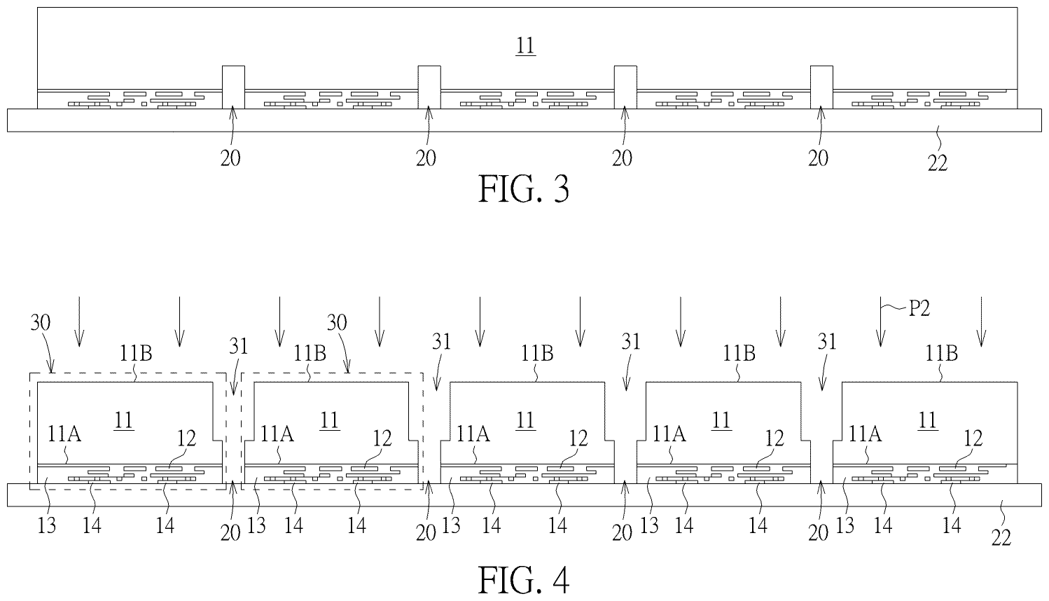

FIG. 2, FIG. 3 and FIG. 4 are schematic cross-sectional views of a wafer dicing step according to an embodiment of the present invention. First, as shown in FIG. 2, the wafer 10 shown in FIG. 1 is subjected to the dicing step of the present invention. As shown in FIG. 2, a dry etching step P1 is performed to form a plurality of grooves 20 in the non-circuit region R2 by dry etching, wherein the dry etching step includes methods such as plasma, reactive ion etching (RIE) or gas etching, and the dry etching step does not include a laser step, because dicing by the laser step as described above is easy to generate residues such as slag. Taking this embodiment as an example, the dry etching step P1 includes etching with CF₄ or SF₆ gas. The formed groove 20 will penetrate the multi-layer dielectric layer 13 in the non-circuit region R2 and etch a part of the substrate 11, but the groove 20 does not penetrate the whole substrate 11.

It is worth noting that the groove 20 in the substrate 10 is formed by dry etching, which does not produce residues such as slag, and the dry etching step is not easy to damage the hybrid contact structure 14 on the surface. Therefore, the surface flatness of the hybrid contact structure 14 can be maintained to the greatest extent.

Next, as shown in FIG. 3, the wafer 10 is turned upside down, and a dicing tape 22 is attached to the front surface 11A of the wafer 10. Among them, the dicing tape 22 has two functions, one of which is to protect various components on the front surface 11A of the wafer 10, including the above-mentioned hybrid contact structure 14, and prevent these components from being contaminated in the subsequent steps. The other function of the dicing tape 22 is used to fix the wafer so that it is not easy to move during the dicing step and improve the dicing accuracy.

As shown in FIG. 4, a blade saw step P2 is performed from the back surface 11B of the substrate 11, and a plurality of dicing grooves 31 are formed on the back surface 11B of the substrate 11. The dicing groove 31 corresponds to the position of the groove 20 of the front surface 11A, and the dicing groove 31 is connected to the groove 20 and cuts the substrate 11. Compared with the dry etching step P1, the blade saw step P2 described here has worse accuracy, so the roughness of the cut surface is also higher, but the dicing rate of the blade saw step P2 is faster. Therefore, in the present invention, the blade saw step P2 is performed from the back surface 11B of the substrate 11, and a part of the substrate 11 is performed by the faster blade saw step P2, so that the overall wafer dicing rate can be improved. In addition, the blade saw step P2 cuts from the back surface 11B of the substrate 11, and the back surface 11B of the substrate 11 does not contain various electronic components such as the hybrid contact structure 14, so even if the blade saw step P2 produces a rough section, it has little influence on the quality of the semiconductor die after dicing. After the blade saw step P2, the wafer 10 is divided into a plurality of dies 30, and then the dicing tape 22 is removed. Subsequently, other processes can be performed on each die 30, such as bonding each die 30 to another wafer (not shown).

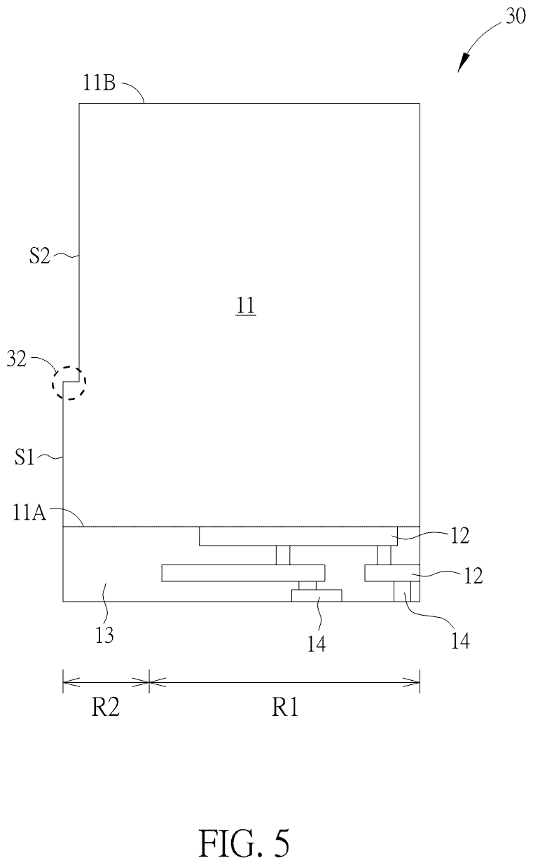

FIG. 5 shows a schematic cross-sectional structure of a cut die 30. As shown in FIG. 5, the die 30 includes a substrate 11, and the substrate 11 includes a front surface 11A and a back surface 11B. The front surface 11A includes multiple circuit layers 12 located in the dielectric layer 13, and includes a hybrid contact structure 14 exposed by the dielectric layer 13. The materials and characteristics of the circuit layer 12, the dielectric layer 13 and the hybrid contact structure 14 described here are the same as those described above, and they are not repeated here.

It is worth noting that, as seen from FIG. 5, one side of the substrate 11 contains a stepped sharp corner portion 32, in which the sharp corner portion 32 is formed due to the difference in accuracy between the dry etching step P1 and the blade saw step P2. Since the width of the dicing groove 31 of the back surface 11B of the substrate 11 formed by the blade saw step P2 is larger than the width of the above-mentioned groove 20, therefore, at the overlap of the groove 20 and the dicing groove 31, the widths of the two grooves are different, so that the sharp corner portion 32 is generated. A sharp angle is, for example, an angle close to a right angle. In addition, as seen from FIG. 5, the sidewalls below and above the sharp corner portion 30 are defined as side surface S1 and side surface S2, respectively, and the surface roughness of the side surfaces S1 and S2 is also different. Taking this embodiment as an example, the surface roughness of the side surface S1 is lower than that of the side surface S2, because the side surface S1 is produced by the dry etching step P1, which belongs to the side of the groove 20, and the side surface S2 is produced by the blade saw step P2, which belongs to the side of the dicing groove 31. As mentioned above, the precision of the dry etching step P1 is higher, so the flatness of the surface or sidewall produced after etching is also better.

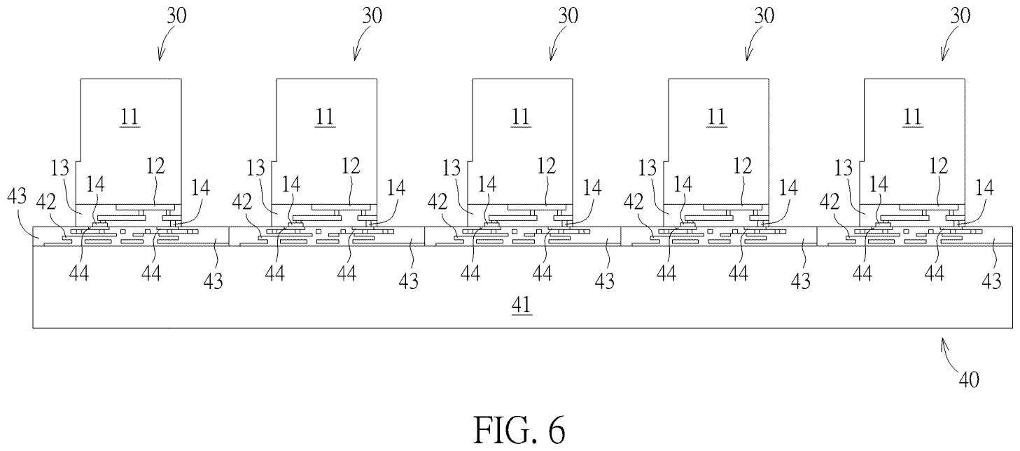

FIG. 6 is a schematic cross-sectional view showing that a plurality of cut dies are bonded to another wafer. As mentioned above, the cut die shown in FIG. 5 can be bonded to another wafer, and as shown in FIG. 6, a plurality of cut dies 30 can be bonded to another wafer 40, in which the wafer 40 may have a structure similar to that of the previous wafer 10, in which the wafer 40 generally includes a substrate 41, a dielectric layer 43 on the substrate 41, a plurality of circuit layers 42 buried in the dielectric layer 43, and the topmost hybrid contact structure 44 exposed by the dielectric layer 43. The hybrid contact structure 14 on the die 30 directly contacts the hybrid contact structure 44 on the wafer 40. It is worth noting that, in order to reduce the process difficulty, it is preferable that the wafer 40 has not been cut during this bonding step, so that the die 30 can be bonded to the wafer 40 with a relatively stable structure. Other dicing steps can be performed later to cut the wafer 40 into a plurality of dispersed dies.

Based on the above description and drawings, the present invention provides a method for dicing a semiconductor structure, which comprises providing a wafer 10 with a front surface 11A and a back surface 11B defined, forming at least one dielectric layer 13 on the front surface 11A of the wafer 10 and at least one first hybrid contact structure 14 located in the dielectric layer 13, wherein the surface of the first hybrid contact structure 14 is exposed, and performing a dry etching step P1, so as to form a plurality of grooves 20 on the front surface 11A of the wafer 10, and performing a blade saw step P2 to form a plurality of dicing grooves 31 from the back surface 11B of the wafer 10 and cut the wafer 10 into a plurality of dies 30.

In some embodiments of the present invention, the position of each dicing groove 31 on the back surface 11B of the wafer 10 corresponds to the position of each groove 20 on the front surface 11A of each wafer 10.

In some embodiments of the present invention, a width of each dicing groove 31 is greater than a width of each groove 20.

In some embodiments of the present invention, after the blade saw step P2, the die 30 includes a sharp corner portion 32.

In some embodiments of the present invention, the sharp corner portion 32 is located in a silicon substrate 11 of the die 30.

In some embodiments of the present invention, the dry etching step P1 includes an etching step in the form of plasma or gas, and the dry etching step P1 does not include laser dicing.

In some embodiments of the present invention, the dry etching step P1 is performed before the blade saw step P2 is performed.

In some embodiments of the present invention, each groove 20 is located in a plurality of non-circuit regions R2 on the wafer 10.

In some embodiments of the present invention, the each groove 20 is disposed in the silicon substrate 11 of the wafer 10.

In some embodiments of the present invention, a plurality of conductive layers (i.e., the circuit layers 12) and a plurality of dielectric layers 13 are formed on the front surface 11A of the wafer 10.

In some embodiments of the present invention, the hybrid contact structures 14 are formed before the grooves 20 are formed.

In some embodiments of the present invention, after the grooves 20 are formed, the front surface 11A of the wafer 10 is attached to a dicing tape 22.

In some embodiments of the present invention, after the blade saw step P2 is completed, the wafer 10 is cut into a plurality of dies 30, and each die 30 is then removed from the dicing tape 22.

In some embodiments of the present invention, each die 30 is bonded to another wafer 40, wherein the other wafer 40 contains a plurality of second hybrid contact structures 44, and the second hybrid contact structures 44 are in direct contact with the first hybrid contact structures 14.

The invention also provides a semiconductor structure, which comprises a die 30, and the die 30 comprises a substrate 11, wherein the substrate 11 comprises a front surface 11A and a back surface 11B, wherein the substrate 11 comprises a sharp corner portion 32, at least one dielectric layer 13 is located on the front surface 11A of the substrate 11, and at least one first hybrid contact structure 14 is located in the dielectric layer 13, wherein the surface of the first hybrid contact structure 14 is exposed.

In some embodiments of the present invention, the material of the sharp corner portion 32 and the material of the substrate 11 are both silicon.

In some embodiments of the present invention, the sharp corner portion 32 comprises a first side surface (i.e., the side surface S1), a second side surface (i.e., the side surface S2) and a horizontal plane (the horizontal plane between the side surface S1 and the side surface S2).

In some embodiments of the present invention, the first side surface S1 is aligned with a sidewall of the dielectric layer 13 in a vertical direction.

In some embodiments of the present invention, the surface roughness of the first side surface S1 is different from that of the second side surface S2, and the surface roughness of the first side surface S1 is lower than that of the second side surface S2.

In some embodiments of the present invention, a wafer 40 is further included, the wafer 40 includes a second hybrid contact structure 44, wherein the first hybrid contact structure 14 on the die 30 is in direct contact with the second hybrid contact structure 44 on the wafer 40.

The present invention is characterized by providing a method for dicing a wafer, especially a method for dicing a wafer containing a hybrid bond contact. Because the wafer contains hybrid contact structures, it requires high surface flatness. If the wafer is cut by conventional methods such as laser dicing or stealth Dicing, it may cause problems such as slag or difficult to control the cross section. The method comprises the following steps: firstly, forming a groove on the front side of a wafer by dry etching, and then dicing the wafer from the back side of the wafer by a blade saw step. The groove on the front side of the wafer is formed by dry etching, so that no slag is generated, the flatness of the hybrid contact structure on the front side of the wafer can be maintained, and the quality of the cut dies can be improved. In addition, the back of the wafer is diced by the blade saw, so that the dicing speed of the wafer can be maintained and the dicing efficiency can be prevented from being excessively slowed down by the etching step.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for dicing a semiconductor structure, comprising:
providing a wafer, wherein the wafer is defined with a front surface and a back surface;
forming at least one dielectric layer on the front surface of the wafer and at least one first hybrid contact structure in the dielectric layer, wherein the surface of the first hybrid contact structure is exposed;
performing a dry etching step to form a plurality of grooves on the front surface of the wafer; and
performing a blade saw step, forming a plurality of dicing grooves from the back of the wafer, and dicing the wafer into a plurality of dies.

2. The method for dicing a semiconductor structure according to claim 1, wherein the position of each dicing groove on the back surface of the wafer corresponds to the position of each groove on the front surface of each wafer.

3. The method for dicing a semiconductor structure according to claim 1, wherein a width of each dicing groove is greater than a width of each groove.

4. The method for dicing a semiconductor structure according to claim 1, wherein after the blade saw step, the die includes a sharp corner portion.

5. The method for dicing a semiconductor structure according to claim 4, wherein the sharp corner portion is located in a silicon substrate of the die.

6. The method for dicing a semiconductor structure according to claim 1, wherein the dry etching step includes an etching step by plasma or gas, and the dry etching step does not include laser dicing.

7. The method for dicing a semiconductor structure according to claim 1, wherein the dry etching step is performed before the blade saw step.

8. The method for dicing a semiconductor structure according to claim 1, wherein each of the grooves is located in a plurality of non-circuit regions on the wafer.

9. The method for dicing a semiconductor structure according to claim 1, wherein each groove disposed in a silicon substrate of the wafer.

10. The method for dicing a semiconductor structure according to claim 1, further comprising forming a plurality of conductive layers and a plurality of dielectric layers on the front surface of the wafer.

11. The method for dicing a semiconductor structure according to claim 1, wherein the hybrid contact structure is formed before each groove is formed.

12. The method for dicing a semiconductor structure according to claim 1, further comprising:
attaching the front surface of the wafer to a dicing tape after forming each groove;
the wafer is cut into the plurality of dies after the blade saw step is performed; and
removing each die from the dicing tape after the wafer is cut into a plurality of dies.

13. The method for dicing a semiconductor structure according to claim 12, wherein each of the dies is bonded to another wafer, wherein the another wafer contains a plurality of second hybrid contact structures, and the second hybrid contact structures are in direct contact with the first hybrid contact structures.

14. A semiconductor structure comprising:
a chip, which comprises a substrate with a front surface and a back surface, wherein the chip comprises an element region and a non-circuit region, and the non-circuit region is at one side of the element region, wherein the substrate comprises a sharp corner portion, and the sharp corner portion is located in the non-circuit region;
at least one dielectric layer located on the front surface of the substrate, and located in the element region and the non-circuit region; and
at least one first hybrid contact structure located in the dielectric layer and in the element region, wherein the surface of the first hybrid contact structure is exposed.

15. The semiconductor structure according to claim 14, wherein the non-circuit region does not include a metal layer.

16. The semiconductor structure according to claim 14, wherein the material of the sharp corner portion and the material of the substrate are both silicon.

17. The semiconductor structure according to claim 14, wherein the sharp corner portion comprises a first side surface, a second side surface and a horizontal plane connecting the first side surface and the second side surface.

18. The semiconductor structure according to claim 16, wherein the first side surface is aligned with a sidewall of the dielectric layer in a vertical direction.

19. The semiconductor structure according to claim 16, wherein the first side surface and the second side surface have different surface roughness.

20. The semiconductor structure according to claim 14, further comprising a wafer comprising a second hybrid contact structure, wherein the first hybrid contact structure on the die is in direct contact with the second hybrid contact structure on the wafer.
